(19) United States
(12) Patent Application Publication
(10) Pub. No.: US 2003/0222320 A1
(43) Pub. Date: Dec. 4, 2003

(54) Prevention of defects in forming a metal silicide layer

(76) Inventor: Junichi Nozaki, Fukuyama (JP)

Correspondence Address: BIRCH STEWART KOLASCH & BIRCH, PO BOX 747, FALLS CHURCH, VA, 22040-0747, US

(21) Appl. No.: 10/158,049

(22) Filed: May 31, 2002

(51) Int. Cl. H01L 29/76

(52) U.S. Cl. 257/412

(57) ABSTRACT

A semiconductor device such as a thin film transistor has a silicide layer on the gate, drain, and source electrodes formed without abnormal growth phenomena causing short circuits to occur between the electrodes. The gate of the semiconductor device has side walls such that the metal silicide over the gate is relatively lower than a top portion of each of the wall. The distance between the metal silicide over the gate and the top portion of each side wall can be about 300 angstroms. The metal silicide can be cobalt silicide.

### FIELD OF THE INVENTION

The invention relates to a semiconductor device having a metal silicide layer over a gate electrode.

### BACKGROUND OF THE INVENTION

Metal silicides are generally used for forming the gate, source, and drain electrodes of integrated circuit elements. Refractory metals react with silicon when alloyed together to form a silicide. A silicide is a metal compound that is thermally stable and provides for low electrical resistivity at the silicon/refractory metal interface. Refractory metal silicides are important in wafer fabrication because of the need to reduce the electrical resistance of the many silicon contacts in the source/drain and gate regions for chip performance. Titanium and cobalt are common refractory metals used for contacts in aluminum interconnect technology.

If the refractory metal is reacted with polysilicon, it is called a polycide. Doped polysilicon is used as the gate electrode and has a relatively high resistivity (about 500 μΩ-cm), which leads to an undesirable RC signal delay. A polycide is beneficial for reducing the series resistance of an interconnection to polysilicon. At the same time, it maintains polysilicon's good interfacial characteristics to oxides.

Silicides improve contact resistance by reducing residual oxides on the silicon surface during silicide formation. Silicides form extremely good metallurgic contact to the silicon, thereby serving as a critical adhesion layer between the contact metal and the silicon junction regions. Many silicides are stable at temperatures exceeding 100° C. with a relatively high eutectic temperature. Table 1 lists some properties of common silicides used in wafer fabrication.

TABLE 1

| | Lowest | Typical | |
|---|---|---|---|
| | Eutectic | Forming | |
| | Temperature | Temperature | Resistivity |
| Silicide | (° C.) | (° C.) | (μΩ-cm) |
| CoSi₂ | 900 | 550-700 | 13-19 |
| MoSi₂ | 1410 | 900-1100 | 40-70 |
| PtSi | 830 | 700-800 | 28-35 |
| TaSi₂ | 1385 | 900-1100 | 35-55 |
| TiSi₂ | 1330 | 600-800 | 13-17 |
| WSi₂ | 1440 | 900-1100 | 31 |

Silicide formation conventionally entails depositing the refractory metal on the silicon wafer, followed by high temperature thermal annealing. The thermal annealing often is a rapid thermal annealing in a multichamber cluster tool. The silicide forms in areas where there is silicon available to react with the metal. No silicide forms in other areas on the wafer, such as where there is SiO₂

TiSi₂ has traditionally been the most commonly used contact silicide in wafer fabrication, serving as the contact interface between the active regions of silicon and the tungsten plug. As such, it is often referred as the “glue” that holds the silicon and tungsten together. TiSi₂ is stable at high temperatures, is compatible with self-aligned contact processing, has low resistivity compared to other suicides, and is compatible with TiN barrier metals.

TiSi₂ forms two different grain phases. The C49 phase of TiSi₂ forms at an annealing temperature of about 625-675° C. with a resistivity of about 60-65 μΩ-cm. The C54 phase is formed in a second annealing and requires a temperature of at least 800° C. The C54 phase has much lower resistivity of only about 10-15 μΩ-cm, which lowers the overall contact resistance.

However, TiSi₂ has limitations as a contact silicide in sub-0.25 μm technologies. Contacts for ultra-shallow source and drain junctions are becoming thinner. In thin contacts, the TiSi₂ resistivity increases. Additionally, it becomes more difficult to perform the second high temperature annealing step because of critical time and temperature requirements.

The silicide that appears most promising for the 0.18 μm (and smaller) technologies is cobalt silicide (CoSi₂). CoSi₂ maintains a reduced contact resistance of about 13-19 μΩ-cm after annealing, even at the 0.18 μm geometry. This reduced resistivity appears to be due to the grain size of CoSi₂ being about ten times smaller than the grain size of TiSi₂. As a result, a low resistance phase is completely nucleated and grown during the thermal annealing step. A CoSi₂ contact is easier to form because of the small grain size.

An example of the conventional formation of cobalt silicide electrodes will be explained with reference to FIGS. 2(a) and 2(b).

FIG. 2(a) shows a semiconductor substrate 200 having a p-type or n-type well layer 201. Over this, isolation region 202, gate oxide film 203, polycrystalline silicon gate electrode 204, impurity diffusion layer 205, and side wall 206 are formed. An oxide film is deposited thereon as a sacrificial oxide film, impurities are implanted into the gate, source, and drain electrodes, and activation annealing is conducted.

Next, as shown in FIG. 2(b) after stripping the sacrificial oxide layer, cobalt thin film 207 and titanium nitride thin film 208 are deposited in sequence by sputtering for example. Thereafter, a heat treatment is conducted at approximately 500° C. in a nitrogen atmosphere. This causes a high-resistance phase of CoSi₂ to form at the interface between cobalt thin film 207 and polycrystalline silicon gate electrode 204.

Then, after stripping the cobalt thin film 207 and titanium nitride thin film 208 (which are unreacted layers) with a liquid mixture of sulfuric acid and aqueous hydrogen peroxide, a heat treatment is conducted at approximately 800° C. in a nitrogen atmosphere. As a result, the high-resistance phase Of CoSi₂ converts to a low-resistance phase of CoSi₂ and a silicide layer 209 is formed, as shown in FIG. 2(c). In this conventional art technology the silicide layer conforms with the topology on top of the gate. That is, the silicide is substantially flush with the upper portions of the side walls. Further, as is shown in FIG. 3(b), the gate silicide layer can overlap the top portion of the side walls to result in an abnormal growth pattern. This abnormal growth pattern brings both the source and drain silicide layers in sufficient proximity with the gate silicide layer to cause deleterious effects such as increased leakage current and a significant probability of shorts occurring.

Also, it is difficult for a silicide layer to form on side wall 206. As a result, unreacted substances may adhere to the side wall to cause defects, leakage current and shorts. The removal of unreacted substances on this side wall 206 is extremely important. A method that utilizes the difference in adhesion is presented in Laid-Open Japanese Patent Publication No. 7-106564.

In the conventional technology the gate silicide film can overlap the side wall, and the metal silicide thin film grown abnormally on the side wall is difficult to remove. Unreacted substances may also be on the side wall. The abnormally grown silicide layer causes such problems as increased leakage current and short circuits between the gate electrode and the drain and source electrodes.

### SUMMARY OF THE INVENTION

The invention, in part, pertains to gate silicide layer having reduced current leakage and less tendency to short circuit.

The invention, in part, pertains to the suppression of abnormal silicide growth on the side wall of a gate.

The invention, in part, pertains to a semiconductor device comprising a substrate, a source, a gate and a drain over the substrate, the gate having side walls, and a metal silicide layer over at least a portion of each of the source, the gate and the drain, wherein the metal silicide over the gate is relatively lower than a top portion of each side wall. The metal silicide can be at least one of TiSi₂, CoSi₂, MoSi₂, PtSi, TaSi₂ or WSi₂. The metal silicide layer over the gate can be about 300 Å lower than the top portion of each side wall.

The invention, in part, pertains to a method of manufacturing a semiconductor device which includes forming a polycrystalline film over a substrate, forming a silicon oxide film over the polycrystalline film, forming a gate electrode pattern over the silicon oxide film, etching to form a gate electrode, forming side walls of the gate electrode, the side walls having a portion higher than a surface of the gate electrode, forming a metal film over the gate electrode, forming a metal nitride film over the metal film, and heat treating to form a metal silicide. The upper surface of the metal silicide is lower than a top portion of the gate side walls.

The invention, in part, pertains to forming a side wall for a semiconductor device, whose top part is in a position higher than the upper end of the gate electrode. Consequently, during metal silicide formation, the metal thin film and a cap layer are separated into portions lying on the gate electrode and portions lying on the side wall. As such, abnormal formation of a metal silicide thin film on the side wall is suppressed.

It is to be understood that both the foregoing general description and the following detailed description are exemplary and explanatory and are intended to provide further explanation of the invention as claimed.

### BRIEF DESCRIPTION OF THE DRAWINGS

The accompanying drawings are including to provide a further understanding of the invention. The drawings illustrate embodiments of the invention and together with the description serve to explain the principles of the embodiments of the invention.

FIGS. 1(a)-1(g) are schematic cross sectional views showing the process steps of the present invention.

FIGS. 2(a)-2(c) are schematic cross sectional views showing examples of a conventional method of manufacturing a silicide layer.

FIGS. 3(a) and 3(b) are schematic cross sectional views showing a gate electrode after formation of a silicide layer by the method of the present invention and by a conventional method.

### DETAILED DESCRIPTION OF THE PREFERRED EMBODIMENTS

Advantages of the present invention will become more apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

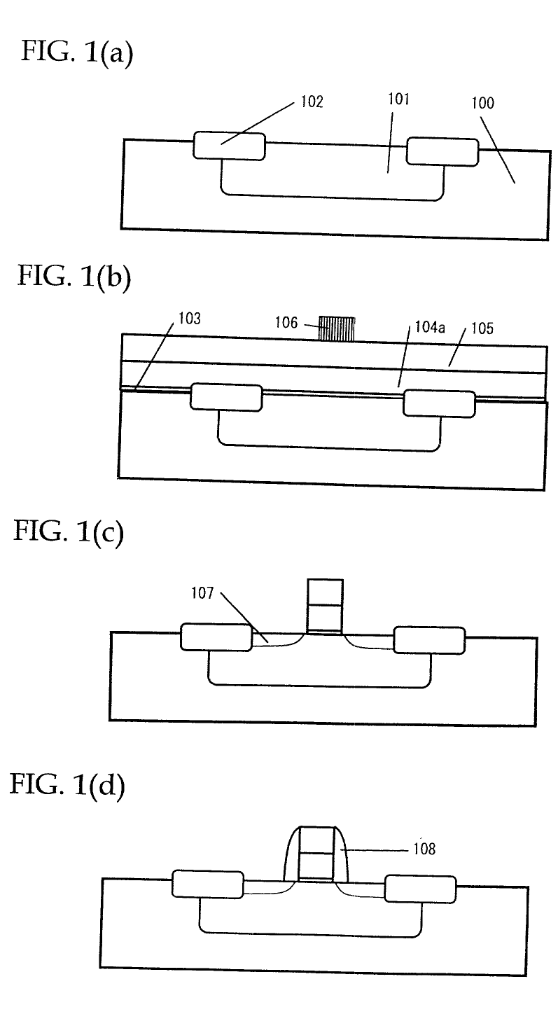

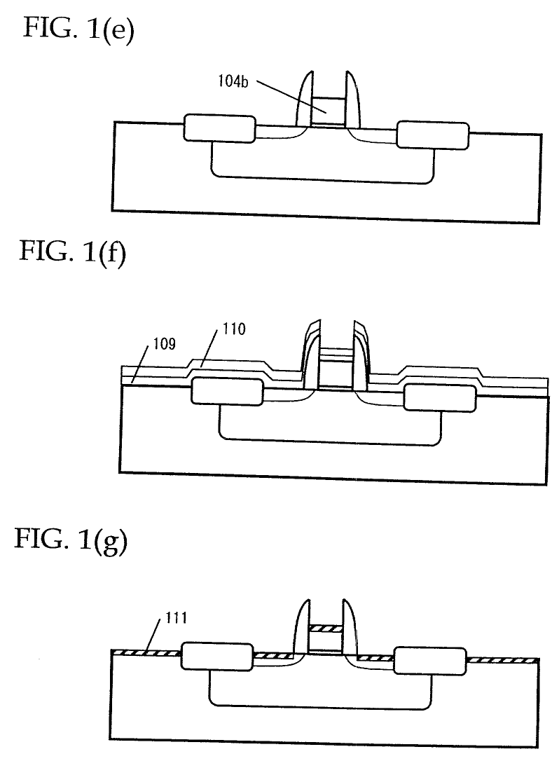

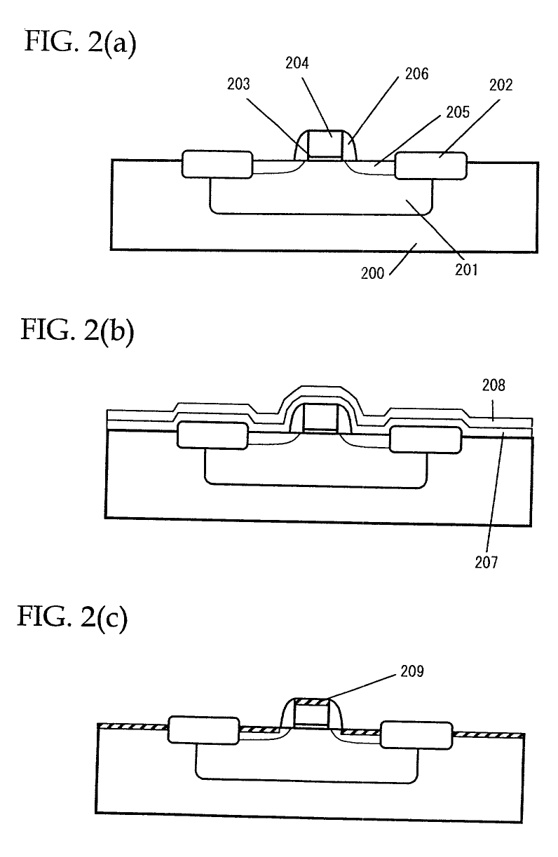

An embodiment of the invention is shown in FIG. 1(a). A p-type or n-type well region 101 and an isolation region 102 of a semiconductor device are formed on a semiconductor substrate 100. Gate oxide film 103 and polycrystalline silicon film 104a are deposited thereon. Then, a side wall is formed, using a method described, for example, by M. Sekine et al., Self-Aligned Tungsten Strapped Source/Drain and Gate Technology Realizing the Lowest Sheet Resistance for Sub-quarter Micron CMOS, IEDM 94-493 (IEEE 1994), the entire content of which is incorporated by reference.

As shown in FIG. 1(b), silicon oxide film 105 is deposited on polycrystalline silicon film 104. A CVD method can be used to deposit the silicon oxide film 105. A gate electrode pattern 106 is formed using photoresist. The thickness of the silicon oxide film is preferably approximately 50 nm and it is further preferred that the silicon oxide film be relatively thicker than the metal thin film 109 and metal nitride thin film 110 shown in FIG. 1(f). That is, if the metal thin film 109 is about 100 Å thick and the metal nitride thin film is about 100 Å thick, it is preferable that the patterned silicon oxide film be greater than about 200 Å thick. The metal thin film is preferably cobalt, and the metal nitride film is preferably titanium nitride.

Gate electrode 104b is formed by removing silicon oxide film 105 and polycrystalline silicon film 104a by means of dry etching for example, and by stripping photoresist 106, by means of ashing for example. Additionally, impurity diffusion layer 107 is formed, preferably by ion implantation.

Next, a silicon oxide film and a silicon nitride film are deposited and then etched to form side wall 108, as shown in FIG. 1(d). Here, as shown in FIG. 1(e), a side wall whose top part is at a position relatively higher than the upper end of the gate electrode can be formed by stripping the aforementioned silicon oxide film 105, using wet etching for example. The wet etching removes the silicon oxide while leaving the underlying polycrystalline film 104b to leave a gate structure having side walls relatively higher than the gate. This relative distance is preferably greater or equal to about 300 Å.

Afterwards, an oxide film that serves as a sacrificial oxide layer is deposited thereon, impurities are implanted into the gate, source, and drain electrodes, and activation annealing is conducted.

Next, as shown in FIG. 1(f), the sacrificial oxide film is stripped and a metal thin film 109 and a metal nitride thin film 110 are deposited in sequence, by sputtering for example. The metal thin film is preferably cobalt, and the metal nitride film is preferably titanium nitride. In the preferred embodiment of the invention, the cobalt thin film 109 has a thickness of about 100 Å, and the titanium nitride film has a thickness of about 100 Å. Due to the height difference between the upper end of the gate electrode and the upper end of the side wall, cobalt thin film 109 and titanium nitride thin film 110 are both deposited such that the portions thereof on gate electrode 104b are separated from the portions thereof on side wall 108. That is, a cap layer of the cobalt thin film 109 and the nitride thin film 110 are separated into portions lying on the gate electrode and portions lying on the side wall 108.

Next, a heat treatment is conducted, preferably at approximately 500° C. in a nitrogen atmosphere or other inert atmosphere. Then, cobalt thin film 109 and titanium nitride thin film 110 (which are unreacted layers) are stripped using an aggressive solvent such as a liquid mixture of sulfuric acid and aqueous hydrogen peroxide. This mixture of sulfuric acid and hydrogen peroxide is referred to as piranha. Afterwards, a heat treatment is conducted, preferably at approximately 800° C. in a nitrogen atmosphere or other inert atmosphere.

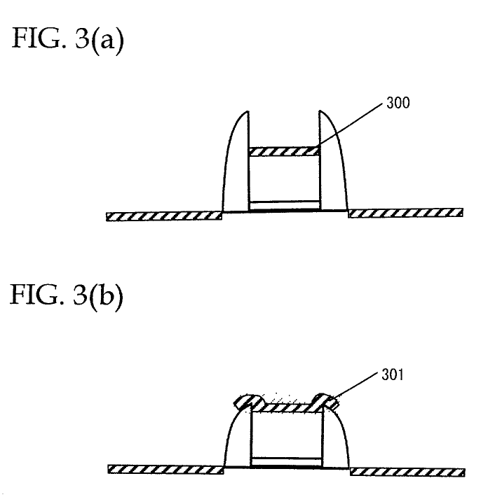

As a result, cobalt silicide layer 111 (see FIG. 1(g)) is formed at the interface between cobalt thin film 109 and polycrystalline silicon film 104. A silicide layer does not form on side wall 108 by abnormal growth and short circuits between the gate electrode and the drain and source electrodes do not occur. FIG. 3(a) shows a schematic cross sectional view of a gate electrode after forming a silicide by this method. The cobalt silicide layer 300 of the gate is lower than the top portion, i.e., tip, of the side wall 108. The distance between the cobalt silicide layer 300 and the tip of the side wall 108 is preferably about 300 Å.

FIG. 3(b) shows a schematic cross sectional view of a gate electrode formed by a conventional method. Here, the cobalt silicide layer 301 overlaps the side wall of the gate. As a result, there is a clear predisposition of this geometry to result in current leakage both between the source and the gate and between the gate and the drain. The closer proximity of source, gate and drain silicide layers additionally raise the probability of shorts. In contrast, the silicide layer 300 of the invention (shown in FIG. 3(a)) is fully shielded by the silicon oxide side wall 108. That is, in the invention the metal silicide layer does not overlap the side wall. As a result the invention has prevented the formation of silicide abnormalities on the side wall, and the deleterious properties caused by these abnormalities has been removed.

Therefore, the present invention makes it possible to obtain a silicide layer on the gate, drain, and source electrodes without abnormal growth phenomena causing short circuits to occur between the electrodes.

It should be noted that the present invention is not limited to use of a cobalt thin film 109, as any relatively high melting point material can be used. This includes, but is not limited to cobalt (Co), tungsten (W), platinum (Pt) tantalum (Ta), titanium (Ti), nickel (Ni), zirconium (Zr), hafnium (Hf), vanadium (V), niobium (Nb), chromium (Cr), molybdenum, (Mo), manganese (Mn), iron (Fe), iridium (Ir), and palladium. Also, nitrides of the aforementioned metals can be used, which preferably is titanium nitride. The resulting metal silicide is preferably one of TiSi₂, CoSi₂, MoSi₂, PtSi, TaSi₂ or WSi₂, but is not restricted to these materials.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

I claim:

1. A semiconductor device comprising:
a substrate;
a source, a gate and a drain over the substrate;
the gate having side walls; and
a metal silicide layer over at least a portion of each of the source, the gate and the drain, wherein the metal silicide over the gate is relatively lower than a top portion of each side wall.

2. The semiconductor device of claim 1, wherein the metal silicide is at least one selected from the group consisting of TiSi₂, CoSi₂, MoSi₂, PtSi, TaSi₂ and WSi₂.

3. The semiconductor device of claim 1, wherein the metal silicide layer over the gate is about 300 Å lower than the top portion of each side wall.

4. The semiconductor device of claim 1, wherein the substrate is silicon.

5. The semiconductor device of claim 1, wherein the side wall is silicon nitride.

6. The semiconductor device of claim 1, wherein the metal silicide layer over the gate does not overlap the side wall.

7. The semiconductor device of claim 1, wherein the substrate has a p-type or n-type well region and an isolation region.

8. A method of manufacturing a semiconductor device, which comprises:
providing a substrate;
forming a polycrystalline film over the substrate;
forming a silicon oxide film over the polycrystalline film;
forming a gate electrode pattern over the silicon oxide film;
etching to form a gate electrode,
forming side walls of the gate electrode, the side walls having a portion higher than a surface of the gate electrode;
forming a metal film over the gate electrode;
forming a metal nitride film over the metal film; and
heat treating to form a metal silicide, wherein an upper surface of the metal silicide is lower than a top portion of the gate side walls.

9. The method of claim 8, wherein the metal film is formed from a metal selected from the group consisting of Ti, Co, Pt, Mo, Ta, and W.

10. The method of claim 8, wherein the metal nitride is titanium nitride.

11. The method of claim 8, wherein the metal silicide layer over the gate electrode is about 300 Å lower than the top portion of each side wall.

12. The method of claim 8, wherein the substrate is silicon.

13. The method of claim 8, wherein the side wall comprises silicon nitride.

14. The method of claim 8, wherein the metal silicide layer over the gate does not overlap the side wall.

15. The method of claim 8, wherein the silicon oxide film has a thickness of about 50 nm.

16. The method of claim 8, wherein CVD is used to form the silicon oxide film.

17. The method of claim 8, wherein the etching to form a gate electrode is dry etching.

18. The method of claim 8, wherein the polycrystalline film is polycrystalline silicon.

19. The method of claim 8, wherein the silicon oxide film has a thickness of about 50 nm.

20. The method of claim 8 wherein the heat treating comprises the steps of:
heating at approximately 500° C. in an inert atmosphere;
stripping unreacted metal film and metal nitride; and
heating at approximately 800° C. in an inert atmosphere.

21. The method of claim 20, wherein the stripping is performed using a mixture of sulfuric acid and hydrogen peroxide.

22. The method of claim 20, wherein the inert atmosphere is nitrogen.
